(19) United States
(12) Patent Application Publication
(10) Pub. No.: US 2024/0353094 A1
(43) Pub. Date: Oct. 24, 2024

(54) VAPORIZER

(71) Applicant: Proterial, Ltd., Koto-ku, Tokyo (JP)

(72) Inventor: Akira Sasaki, Mie-gun (JP)

(21) Appl. No.: 18/689,367

(22) PCT Filed: Aug. 31, 2022
(86) PCT No.: PCT/JP2022/032835

§ 371 Date: Mar. 5, 2024

(30) Foreign Application Priority Data
Sep. 9, 2021 (JP) 2021-147115

(51) Int. Cl. F22B 1/28; G03F 7/26; G05D 7/06; H01L 21/67; H05B 3/20

(52) U.S. Cl. CPC F22B 1/284; G05D 7/0635; H05B 3/20; G03F 7/26; H01L 21/67017; H05B 2203/021; H05B 2203/022; H05B 2203/037

(57) ABSTRACT

This vaporizer comprises: a vaporizing unit for vaporizing a precursor to generate a material gas; a gas flow passageway for guiding the generated material gas to the outside of the vaporizing unit; a first heater for heating the vaporizing unit but not heating the gas flow passageway; and a second heater for heating both the vaporizing unit and the gas flow passageway. In variations, one of the first heater and the second heater has a planar shape, and include a portion having a large power consumption and a portion having a small power consumption per unit area.

### FIELD

This invention relates to a vaporizer used for manufacture of a semiconductor.

### BACKGROUND

In a manufacturing process of a semiconductor, various kinds of semiconductor material gases (which will be referred to as “material gases” hereafter) are used according to purposes of the process. Among them, material gases stored in a state of liquid are supplied to semiconductor producing equipment after their liquid is vaporized by using a vaporizer and changed into a gaseous state. As means for generating the material gases in a vaporizer, for example, there is a method in which the liquid stored in a tank is heated to generate vapor, etc. Opportunities for using material gases which have low equilibrium vapor pressure as compared with conventional material gases and, therefore, is hard to be vaporized are increasing according to progress of semiconductor production technology (see, e.g., Japanese Patent Application Laid-Open (kokai) No. 2009-74108 (PTL1)).

In order to efficiently supply a material gas with low equilibrium vapor pressure in a vaporizer of a type which heats its liquid, it is effective to raise the temperature for heating a tank higher than conventional temperature to raise the vapor pressure of the material gas (these, e.g., Akira Sasaki, “Vaporizer with Higher Applicable Temperature”, Hitachi Metals technical report, 2012, the 28th volume, p.26-29 (NPTL1)). If the temperature of the material gas generated in the tank by this method falls in a process for supplying the material gas to semiconductor producing equipment, the material gas will easily condense to return to its liquid. Therefore, various means for preventing material gas from condensing inside piping have been examined.

For example, Japanese Patent Application Laid-Open (kokai) No. H02-255595 (PTL2) discloses a means for surrounding circumference of a tank in which liquid is stored and circumference of piping, a mass flow controller and a valve through which a vaporized gas flows respectively by individual air thermostatic chambers to maintain the insides of these two air thermostatic chambers at constant temperature. Moreover, for example, Japanese Patent Application Laid-Open (kokai) No. 2003-273026 (PTL3) discloses a means for disposing heating devices which heat a tank, a flow meter and a flow control valve respectively and exclusively. Furthermore, for example, Japanese Patent Application Laid-Open (kokai) No. H11-63400 (PTL4) discloses a means for winding a tape-shaped heater which heats piping through which a material gas flows around the surroundings of the piping.

### SUMMARY

An aspect may be characterized as a vaporizer which supplies a material gas to semiconductor producing equipment. The vaporizer comprises a vaporization part which vaporizes a precursor to generate said material gas and a gas passage which leads said generated material gas to the outside from said vaporization part. A first heater is configured to heat said vaporization part and does not heat said gas passage, and a second heater is configured to heat both said vaporization part and said gas passage. The second heater itself has a planar shape, said vaporization part is located on a side of one surface of said second heater, and said gas passage is located on a side of the other surface of said second heater.

Another aspect may be characterized as a method for supplying a material gas to semiconductor producing equipment by using a vaporizer. The method comprises vaporizing a precursor with a vaporization part to generate said material gas, leading said generated material gas with a gas passage which leads to the outside from said vaporization part, heating said vaporization part with a first heater which heats without heating said gas passage, and heating both said vaporization part and said gas passage with a second heater. The method also comprises controlling electric power to said first heater and electric power to said second heater such that a temperature of said gas passage becomes higher than a temperature of said precursor in said vaporization part.

### BRIEF DESCRIPTION OF DRAWINGS

FIG. 1 is a fragmentary sectional view for showing a first working example of a vaporizer according to the present invention.

FIG. 2 is a fragmentary sectional view for showing a second working example of the vaporizer according to the present invention.

FIG. 3 is a piping diagram for showing a third working example of the vaporizer according to the present invention.

FIG. 4 is a top view for showing the third working example of the vaporizer according to the present invention.

FIG. 5 is a fragmentary sectional side view for showing the third working example of the vaporizer according to the present invention.

FIG. 6 is a plan view for showing an example of a first heater according to the present invention.

FIG. 7 is a plan view for showing an example of a second heater according to the present invention.

FIG. 8 is a plan view for showing an example of a third heater according to the present invention.

### DETAILED DESCRIPTION

When temperature inside a vaporizer is controlled by using the air thermostatic chamber disclosed by the Patent Literature 2, it is difficult to keep uniform a temperature distribution inside an air thermostatic chamber unless space for circulating air around the tank and piping is provided widely to raise efficiency of heat exchange. Moreover, a space for a fan for circulating the air is also needed. For this reason, there is a subject that the size of the vaporizer becomes larger and a compact vaporizer cannot be designed. Furthermore, there is a risk of a failure since a fan has a moving part.

When the exclusive devices disclosed in the Patent Literature 3 are disposed, there is a subject that a difference in temperature easily occurs according to positions in the passage through which the material gas passes since the thermostatic chamber is lacked. The higher retention temperature becomes, the more remarkable this subject becomes. When the tape-shaped heater disclosed in the Patent Literature 4 is disposed, it cannot be avoided that an individual difference among apparatuses arises at a position where the heater is attached and the contact area with the piping, and/or the position shifts while using the heater for a long period of time. For this reason, there is a subject that the performance of the vaporizer cannot be stabilized.

The present disclosure has been made in light of the above-mentioned subjects, and one of its objectives is to realize a vaporizer which is compact and excellent in thermal uniformity.

### Solution to Problem

In a certain embodiment, the present disclosure relates to a vaporizer which supplies a material gas to semiconductor producing equipment, comprising a vaporization part which vaporizes a precursor to generate the material gas, a gas passage which leads the generated material gas to the outside from the vaporization part, a first heater which heats the vaporization part and does not heat the gas passage, and a second heater which heats both the vaporization part and the gas passage.

In the above-mentioned configuration, since the vaporization part can be heated with two heaters, the first heater and the second heater, temperature distribution of the vaporization part becomes more uniform than that in a conventional technology. Moreover, since the second heater is used for heating both the vaporization part and the gas passage, it becomes possible to reduce the number of the sum totals of heaters and to design a compacter vaporizer, as compared with a conventional technology.

In another embodiment, the present disclosure relates to the vaporizer wherein at least one of the first heater and the second heater has a part with a large power consumption per unit area and a part with a small power consumption per unit area, in the above-mentioned configuration. In this embodiment, a part in which fall of the temperature accompanying vaporization and flow of the material gas is remarkable can be heated preferentially among the parts heated with the heaters. Furthermore, in another embodiment, the present disclosure also relates to a method for supplying a material gas by using a vaporizer.

### Advantageous Effects of Invention

In accordance with the present disclosure, temperature balance of a whole vaporizer can be improved by a compact configuration without a thermostatic chamber, and power consumption by the vaporizer can be reduced.

### DESCRIPTION OF EMBODIMENTS

Embodiments of the present invention will be explained in detail below. Following explanations and drawings show examples of the embodiments of the present invention, and embodiments of the present invention are not limited to the form shown in the following explanations and drawings. In addition, in the present specification, the terms “top” and “bottom” are defined on the basis of a direction of the gravity in a state where a vaporizer is installed and used in a production line of a semiconductor.

### 1. First Embodiment

In a first embodiment, the invention is a vaporizer for supplying material gas to a semiconductor producing equipment, which comprises a vaporization part which vaporizes a precursor to generate the material gas, a gas passage which leads the generated material gas to the outside from the vaporization part, a first heater which heats the vaporization part and does not heat the gas passage, and a second heater which heats both the vaporization part and the gas passage.

### <Vaporizer>

In the present specification, a “vaporizer” refers to equipment which supplies material gas produced by vaporizing a precursor to semiconductor producing equipment. Generally, baking, bubbling and direct vaporization methods are known as means for vaporizing a precursor in a vaporizer. A vaporizer according to the present invention should comprise means for vaporizing a precursor into a gaseous state, and this means may be any one of the above-mentioned known means. Alternatively, this means may be a novel means which belongs to none of the above-mentioned means.

### <Material Gas>

In the present specification, a “material gas” refers to a gas used in a manufacturing process of a semiconductor, which is stored in a form of a liquid or solid precursor and requires an operation to be vaporized or sublimated to be change into a gas when used. A material gas in the present specification is a concept which includes not only gases used as materials for patterned elements, conductors or insulating layers constituting a semiconductor device, but also any gases used in manufacturing process of a semiconductor, such as gases used in an etching process of a semiconductor device. In the present specification, a “precursor” refers to a substance in a stage before the material gas is generated.

### <Vaporization Part>

The vaporizer according to the present invention comprises a vaporization part which vaporizes a precursor to generate said material gas. The vaporization part may have any structure as long as it has a function for heating and vaporizing the precursor. When the baking method is adopted as a means for vaporizing the precursor, the vaporization part can be constituted by a tank containing a liquid or solid precursor. The tank is not limited in shape as long as it has a closed space defined by partitions.

As for a means for storing the precursor in the tank, when the precursor is a liquid, the precursor can be charged into the tank using piping provided in connection with the tank. When the precursor is a solid, the precursor can be stored in the tank charging the precursor into the tank through an opening provided in a part of the partition of the tank and thereafter sealing the opening with a lid. The tank can be equipped with sensors to detect the remaining amount, temperature and pressure of the precursor, etc.

When the bubbling method is adopted as the method for vaporizing the precursor, the vaporization part can be constituted by a tank for containing the liquid precursor and piping for introducing the carrier gas into the tank. When the direct vaporization method is adopted as the method for vaporizing the precursor, the vaporization part can be constituted by piping for continuously introducing the liquid precursor and the gaseous carrier gas, respectively, and means for continuously heating them. Even when either one of the above-mentioned means is adopted, the precursor is vaporized inside the vaporization part to generate the material gas.

When the precursor is a liquid, in the baking and bubbling methods, the generated gas accumulates in a space above a liquid level of the precursor stored in the tank. In this case, the tank may be large enough in volume to contain a sufficient quantity of the precursor required for supplying the material gas, or the tank itself constituting the vaporization part may be constituted to have a small volume and the precursor contained in another storage container which has larger volume may be replenished to the vaporization part as needed. In the direct vaporization method, a liquid precursor stored in a container separate from the vaporization part are continuously supplied to the vaporization part for vaporization.

### <Gas Passage>

The vaporizer according to the present invention comprises a gas passage which leads the generated material gas to the outside from the vaporization part. In the present specification, a “gas passage” refers to a pathway through which the material gas generated in the vaporization part flows, and is a concept which includes all parts comprising the pathway through which the material gas flows, such as piping, valves which will be mentioned later, a mass flow controller and members belonging to them. When the baking method is adopted as the method for vaporizing the precursor, the vaporized material gas flows through the gas passage. When the bubbling method or direct vaporization method is adopted as the method for vaporizing the precursor, a mixture of the material gas and carrier gas flows through the gas passage.

A starting point of the gas passage is an outflow part of the material gas provided in the vaporization part. When the material gas accumulates in the upper part of the vaporization part as mentioned above, it is preferred that the outflow part of the material gas is provided in the upper part of the vaporization part. An end point of the gas passage is the supply port which supplies the material gas from the vaporizer to the outside, and may protrude from a case of the vaporizer as will be mentioned later. Specifically, a joint for connecting piping which conveys the material gas from the vaporizer to a semiconductor producing equipment corresponds to this. The gas passage having the above-mentioned configuration can lead the material gas generated in the vaporization part from the vaporization part to the outside of the vaporizer. When the temperature of the material gas drops between the starting and ending points of the gas passage, the material gas may condense. For this reason, the gas passage is heated using a second heater which will be mentioned later, to prevent condensation of the material gas. Although a phenomenon in which a material gas generated from a solid precursor returns to a solid state due to a decrease in temperature is sometimes referred to as “solidification,” a phenomenon in which a material gas returns to either a liquid or solid state due to a decrease in temperature is collectively referred to as “condensation” without distinction in the present specification, in order to avoid complications.

In the vaporizer according to the present invention, it is preferred that the gas passage is provided in the vicinity of the vaporization part in respect of electric power efficiency of the second heater which will be mentioned later. In the present specification, “electric power efficiency” refers to a proportion of electric power contributing to the heating of the vaporization part and the gas passage in electric power supplied to the heater. The material gas generated in the vaporization part has a low density and tends to rise. For this reason, it is preferred that the gas passage is provided at a position upper than the vaporization part to make the material gas flow smoothly. However, in the present invention, the position where the gas passage is provided is not limited to the position upper than the vaporization part. The gas passages may be provided on a side face of the vaporization part, for example.

### <First Heater>

The vaporizer according to the present invention comprises a first heater which heats the vaporization part and does not heat the gas passage. The first heater is a member separate and independent from a second heater which will be mentioned later. The first heater has a function for heating the vaporization part, and does not have a function for heating the gas passage, or the effect thereof is limited if it has the function. More specifically, the first heater is provided at a position away from the gas passage or in a state where there is no effective heat transfer path between the first heater and the gas passage. The first heater has a function to heat the vaporization part together with the second heater. Most of the power consumed by the first heater is used to heat the vaporization part.

However, it does not mean that the first heater has no action to heat the gas passage at all. For example, it is permissible in the present invention for the gas passage adjacent to the heated vaporization part to be heated as a result of the vaporization part being heated by the first heater and the second heater. It is permissible in the present invention for a part of the electric power consumed by the first heater to be used to heat another member which is neither the vaporization part nor the gas passage.

In the vaporizer according to the present invention, the first heater is provided at a position different from a position where the second heater is provided. For example, when the second heater is provided at a position upper than the vaporization part, the first heater can be provided at a position lower than the vaporization part or a position at the same height as the vaporization part. It is permissible in the present invention to provide a plurality of the first heaters for a special effect.

In the vaporizer according to the present invention, the first heater can have any specific configuration, as long as it is configured so as to be able to heat the vaporization part by being supplied with electric power. For example, the first heater can comprise a heating resistive element and electric wires for supplying electric power to the heating resistive element. In addition, depending on a configuration of the vaporization part (for example, size, shape and structure, etc.), the heating resistive element may be divided into a plurality of parts, and the heating resistive element divided into a plurality of parts may be constituted to be connected in parallel or in series to be supplied with electric power.

As a means for controlling the electric power supplied to the first heater, well-known temperature control technologies can be used. For example, a temperature sensor can be provided inside the first heater, and feedback control can be performed such that the temperature of the first heater measured by the temperature sensor matches a temperature set in advance. Alternatively, a temperature sensor to measure a temperature of the precursor to be heated by the first heater can be provided, and feedback control can be performed such that the temperature of the precursor measured by the temperature sensor matches a temperature set in advance. The number of the temperature sensors used to control the electric power supplied to the first heater may be one, two or more.

### <Second Heater>

The vaporizer according to the present invention comprises a second heater which heats both the vaporization part and the gas passage. The second heater is a member separate and independent from the above-mentioned first heater. The second heater has both a function for heating the vaporization part and a function for heating the gas passage. A part of the electric power consumed by the second heater is used to heat the gas passage, and the remaining part is used to heat the vaporization part. However, as in the case of the first heater, it is permissible in the present invention for a part of the electric power consumed by the second heater to be used to heat another member which is neither the vaporization part nor the gas passage. When there is only one gas passage, one second heater is usually sufficient. However, it is permissible in the present invention to provide a plurality of second heaters for a special purpose.

As mentioned above, in the present invention, the first heater is primarily responsible for the function of heating the vaporization part. As for the heating of the vaporization part, the second heater plays only an auxiliary role. On the other hand, as for the heating of the gas passage, the first heater makes almost no contribution, and the second heater is solely responsible for that. Thus, by constituting heater used in the vaporizer with the first heater and the second heater and making respective heaters perform different functions, the present invention has the following unique effects not found in a conventional technology.

First, as compared with a conventional technology in which the vaporization part and the gas passage are heated by one dedicated heater for each, although the vaporizer according to the present invention also has two heaters, a temperature distribution in the vaporization part is more uniform than that in the conventional technology since the vaporization part can be heated not by one dedicated heater, but by two heaters, the first heater and the second heater, provided at different positions from each other.

Moreover, as compared with a conventional technology in which two dedicated heaters are used to heat the vaporization part and a third heater is used to heat the gas passage, for a total of three heaters, a more compact vaporizer design can be achieved as compared with the conventional technology since the number of heaters in the present invention can be reduced from three to two without compromising the uniformity of the temperature distribution in the vaporization part.

By the way, if the objective is only to prevent the material gas generated in the vaporizer from condensing inside the gas passage, the above-mentioned objective can be achieved by raising the temperature of the gas passage sufficiently. However, operating only a part of the vaporizer at an excessively high temperature will lead to deterioration of a member at that high temperature part, a decrease in flow accuracy and a decrease in reliability. In addition, the excessively high temperature may change the property of the material gas or thermally decompose the material gas, cause foreign matter derived from the material gas to adhere to the inside of the gas passage or cause blockage in the flow sensor and valves.

Therefore, in an ideal vaporizer, it is desirable to avoid the above-mentioned failures due to the excessive heating of the material gas by uniformly heating the entire gas passage from the outflow part to the supply port of the vaporization part at the lowest necessary temperature. Adopting the first and second heaters according to the present invention as the heating means in the vaporizer is effective in raising the temperature of the entire gas passage uniformly. Thereby, effects, such as improved flow accuracy and reliability of the material gas generated by the vaporizer, a reduced frequency of faults, an improved reliability of a semiconductor production process due to particle suppression and a reduced frequency of maintenance, arise.

In the vaporizer according to the present invention, as in the case of the first heater, the second heater can have any specific configuration, as long as it is configured so as to be able to heat the vaporization part by being supplied with electric power. For example, the second heater can comprise a heating resistive element and electric wires for supplying electric power to the heating resistive element. In addition, depending on configurations of the vaporization part and the gas passage (for example, size, shape and structure, etc.), the heating resistive element may be divided into a plurality of parts, and the heating resistive element divided into a plurality of parts may be constituted to be connected in parallel or in series to be supplied with electric power.

As in the case of the first heater, as a means for controlling the electric power supplied to the second heater, well-known temperature control technologies can be used. For example, a temperature sensor can be provided inside the second heater, and feedback control can be performed such that the temperature of the second heater measured by the temperature sensor matches a temperature set in advance. Alternatively, a temperature sensor to measure a temperature of the gas passage which is one of target to be heated by the second heater can be provided, and feedback control can be performed such that the temperature of the gas passage measured by the temperature sensor matches a temperature set in advance. The number of the temperature sensors used to control the electric power supplied to the second heater may be one, two or more. The temperature measured by one temperature sensor may be commonly used for both controlling the electric power supplied to the first heater and controlling the electric power supplied to the second heater.

### <Second Heater in Planar Shape>

In a preferable embodiment, the present invention is an invention of a vaporizer in which the second heater in the first embodiment has a planar shape, the vaporization part is located on a side of one surface of the second heater, and the gas passage is located on a side of the other surface of the second heater. In the present specification, “the second heater has a planar shape” means that the shape of the second heater itself is thin and flat. The shape of the second heater can be any flat shape, and the shape of the outline of the flat surface is not limited in particular and can be any shape. In addition, the thickness of the second heater may be uniform all over the plane, or conversely, there may be a part with a thickness different from other parts in the second heater.

The second heater having a planar shape needs to be able to supply heat to both one surface and the other surface. In this case, heat supply performance to the other side may be equal to or different from heat supply performance to the one side, but the heat supply performance to either side must not be zero. By having the vaporization part located on the side of the one surface of the second heater and the gas passage located on the side of the other surface of the second heater, heat generated in the second heater is simultaneously distributed to the vaporization part located on the side of the one surface and the gas passage located on the side of the other surface. In other words, the second heater is located between the vaporization part and the gas passage and supplies heat to both of them. In this desirable embodiment, electric power efficiency of the second heater is improved since most of the heat generated in the second heater heats either the vaporization part or the gas passage.

Moreover, in the above-mentioned preferable embodiment, a shape of the heater having a planar shape does not change unlike a tape-shaped heater according to a conventional technology. Therefore, since a mutual positional relationship, such as a distance, between the heater and a target to be heated by the heater is fixed at its design stage and the positional relationship is highly reproducible even when vaporizers with an identical design are repeatedly produced, individual differences among vaporizers with respect to temperature distribution can be reduced. Namely, anyone can produce vaporizers with same performance. In addition, as compared with a tape-type heater, there is less temporal variation in association with long-term use.

<Contact with Second Heater in Planar Shape>

In a more preferable embodiment, the present invention is an invention of a vaporizer in which the vaporization part is not in contact with the one surface of the second heater, and the gas passage is in contact with the other surface of the second heater. In the present specification, “a surface of a heater having a planar shape is in contact with other member” means a state in which the surface of the heater and the other part are in physical contact with each other and heat transfer between the heater and the other member is caused mainly due to heat conduction. In the present specification, “contact” is a concept which includes not only a case where the heater and the other member are in direct contact with each other, but also a case where the heater and the other member are in indirect contact with each other via an intermediate member.

When there is a non-negligible gap between the heater and the other member and heat transfer made between them is caused mainly due to convection or thermal radiation rather than thermal conduction, it does not correspond to the state of “contact” in the present specification. The above-mentioned “a vaporization part is not in contact with one of the surfaces of the second heater” means such a state. Generally, when the temperature difference and other conditions are the same, heat transfer by convection or thermal radiation is slower than heat transfer by thermal conduction.

In this embodiment, the vaporization part is not in contact with the one surface of the second heater, and the vaporization part and the second heater are arranged and fixed at a distance from each other. Although an interval between the vaporization part and the second heater may be a fixed distance, or the distance may change according to positions, there is no part where the distance between the both is zero. Air or an atmosphere gas exists in a gap between the vaporization part and the second heater. Thermal conductivities of these gases are incommensurably smaller than those of solids. Moreover, when the gap is not very large, convection is also unlikely to occur. Therefore, heat generated in the second heater is rarely transferred to the vaporization part by thermal conduction or convection, but the heat is transferred to the vaporization part mainly by thermal radiation. In addition, in the present invention, it is permissible that the second heater and the vaporization part are in indirect contact with each other via a support member with a small cross-sectional area, etc. unless heat conduction via the support member does not significantly affect the effect of the present invention.

On the contrary to this, the gas passage is arranged and fixed in contact with the other surface of the second heater. The contact between the gas passage and the second heater may be either direct contact between both, or indirect contact between the both via an intermediate member provided between the both. From the view point of electric power efficiency of the second heater, it is preferable that the contact is surface-to-surface contact and the intermediate member is constituted by a material which easily conducts heat. In either configuration, a part of heat generated in the second heater is transferred to at least a part of the gas passage mainly by thermal conduction. Only at least a part of the gas passage needs to be in contact with the second heater, and the number of the parts in contact may be one, two or more. By at least a part of the gas passage being in contact with the second heater, that part is heated and condensation of the material gas flowing through the gas passage is prevented.

In accordance with the above-mentioned configuration in the more preferable embodiment, transfer of heat from the second heater to the vaporization part which is not in contact with the second heater is slower than transfer of heat from the second heater to the gas passage which is in contact with the second heater. As a result, heat generated in the second heater is distributed less to the vaporization part and more to the gas passage. In this more preferable embodiment, even when the second heater which is a common heat source is used to heat the gas passage in contact with the second heater at a high temperature, it is possible to prevent temperature of the vaporization part which is not in contact with the second heater from rising too high. As a result, it is possible to heat only necessary parts of the vaporizer while avoiding a localized and excessive temperature rise in the vaporizer. Namely, temperature distribution in the vaporizer can be made to approach the above-mentioned ideal temperature distribution.

From the view point of electric power efficiency of a heater, it is preferable that the contact between one surface of the heater and other member is a surface contact between outer surfaces of the both. It is permissible in the present invention that there is a slight gap of 0.50 mm or less, for example, between the heater and the other member in surface contact with each other, due to machining accuracy and/or unevenness of the surfaces, etc.

From the view point of electric power efficiency of the second heater, it is preferable to prevent condensation of the material gas due to a drop in temperature in a part of the gas passage where the condensation is especially concerned by preferentially making the part contact with the second heater. Specifically, shapes of the surface of the second heater and the part of the gas passage to be preferentially heated can be designed such that they are in direct contact, or an intermediate member can be provided in contact with both the surface of the second heater and the part of the gas passage. In the present invention, as a matter of course, it is permissible as a secondary effect of the second heater that some of the heat generated in the second heater is transferred to a part of the gas passage, which is not in contact with the second heater, by thermal radiation or convection.

As mentioned above, in the configuration of the vaporizer according to the present invention, heat transfer from the second heater to the part of the vaporization part which is not in contact with the second heater is caused mainly by thermal radiation, and heat transfer from the second heater to the gas passage at least partially in contact with the second heater is caused mainly by thermal conduction. When conditions such as a temperature difference and a cross-sectional area are the same, heat transfer by thermal radiation is smaller and less localized as compared with heat transfer by thermal conduction. Therefore, the heat generated in the second heater is distributed more and locally to the gas passage and distributed less to the whole vaporization part. Thereby, even when the gas passage is heated to a temperature at which condensation of the material gas can be prevented, a position close to the second heater in the vaporization part is not excessively heated. As a result, the vaporization part and the gas passage can be heated simultaneously using the second heater which is a common heat source, while reducing problems caused by heating of the vaporization part, and the number of heaters can be reduced and the size of the vaporizer can be reduced.

Moreover, focusing on heating of the entire vaporization part, as mentioned above, in the configuration of the present invention, the vaporization part is heated by two types of heat transfer means: highly efficient heat transfer by heat conduction from the first heater in contact with the vaporization part itself and non-local heat transfer by heat radiation from the second heater which is not in contact with the vaporization part itself. Thereby, since temperature distribution in the entire vaporization part can be made more uniform as compared with that attained by a conventional configuration in which the vaporization part is heated by one, two or more heaters in contact with the vaporization part, for example, supply of the vaporized material gas can be stabilized and the total electric power consumption can be reduced.

<Contact with First Heater in Planar Shape>

In a more preferable embodiment, the present invention is an invention of a vaporizer in which the first heater has a planar shape, and the vaporization part is in contact with one surface of the first heater. In the present specification, “the first heater has a planar shape” means that the shape of the first heater itself is thin and flat, as in the case of the second heater. The shape of the first heater can be any flat shape, and the shape of the outline of the flat surface is not limited in particular and can be any shape. In addition, the thickness of the first heater may be uniform all over the plane, or there may be a part with a thickness different from other parts in the first heater.

In this embodiment, the vaporization part is arranged and fixed in contact with one surface of the first heater. Only at least a part of the vaporization part except the part provided with the second heater needs to be in contact with the first heater, and the number of the parts in contact may be one, two or more. By at least a part of the vaporization part being in contact with the first heater, that part is heated and vaporization of the precursor inside the vaporization part is promoted.

From the view point of electric power efficiency of the first heater, it is preferable to promote vaporization of the precursor in a part of the vaporization part where a drop in temperature due to vaporization of the precursor is especially concerned by preferentially making the part contact with the first heater. For example, when the precursor is a liquid and a means for vaporizing the precursor is the baking or bubbling method, heat of vaporization is lost at a liquid surface of the precursor charged in the tank. In such cases, it is preferable to provide the first heater on a side surface or bottom surface of the tank to control the temperature of the precursor such that the temperature does not fall. When the first heater is provided on the bottom surface of the tank, the first heater does not necessarily have to be provided on the side surface of the tank close to the liquid surface since the temperature of the entire precursor tends to be made uniform by convection.

### <Thermal Uniformity of Tank>

In a preferable embodiment, the present invention is an invention of a vaporizer in which the precursor is a liquid, the vaporization part is a tank which contains the precursor, and the first heater and the second heater are arranged at positions facing each other across the tank. In this embodiment, the precursor is a liquid at room temperature, and the vaporization part is constituted by the tank which contains the liquid precursor. The first and second heaters are arranged at positions facing each other across the tank constituting the vaporization part. Namely, the first heater is arranged in contact with one surface of the tank, and the second heater is arranged not in contact with the tank on a side of the other surface of the tank at a position opposite to the one surface. The surface of the second heater having a planar shape and not in contact with the tank is in contact with the gas passage.

In such an arrangement, the second heater is arranged on a surface farthest from the first heater across the tank. Since this surface is also a surface which is the most unlikely to be heated by the first heater, there is a risk that the vaporized material gas may be cooled and condense close to this surface when the liquid precursor is heated only by the first heater. By placing the second heater on a side of this surface and heating the surface to a moderate temperature, the temperature distribution in the tank can be made uniform. At the same time, since the second heater can also heat the gas passage to an appropriate temperature, the vaporizer comprising the vaporization part and the gas passage as a whole has no places where the temperature is extremely high or low and the electric power efficiency of the heaters is improved.

In a more preferable embodiment, the present invention is an invention of a vaporizer in which the first heater is located in a bottom part of the tank, and the second heater is located in an upper part of the tank. The first heater heats the vaporization part (tank) as mentioned above. Therefore, when the first heater is arranged in the bottom part of the tank, the electric power efficiency of the first heater is improved since the first heater heats a part which is always in contact with the liquid precursor. In addition, a difference between the temperature of the precursor close to the bottom part of the tank and the temperature of the precursor close to a vaporization surface becomes smaller due to convection of the precursor which is a liquid in the tank. Furthermore, since the material gas vaporized at the vaporization surface can convect in a space between the vaporization surface and a ceiling of the tank, an upper part of the tank is also heated to some extent by the material gas. Then, the electric power efficiency of the first and second heaters as a whole is improved since the heating of the tank by the second heater can be reduced.

### <Valve and Mass Flow Controller>

In the desirable embodiment of the present invention, the gas passage includes a valve and a mass flow controller. The valve may have any structure as long as it has a function for closing the gas passage. By operating the valve, supply of the material gas from the vaporizer to semiconductor producing equipment can be instantly stopped or started, even when generation of the material gas in the vaporization part is continuing. The mass flow controller may have any structure as long as it has a function for controlling a flow rate of the material gas flowing through the gas passage. By using the mass flow controller, the flow rate of the material gas supplied from the vaporizer to the semiconductor producing equipment can be controlled to be an arbitrary amount. The above-mentioned valve which closes the gas passage may be substituted by a flow control valve which the mass flow controller comprises.

The valve and mass flow controller themselves comprise individual gas passages. In the above-mentioned preferable embodiment, piping which leads the material gas from the vaporization part to the outside and the individual gas passages which the valve and the mass flow controller individually comprise are joined together to constitute the gas passage in the present invention. The gas passages which the valve and the mass flow controller individually comprise are in contact with the second heater, and heat generated in the second heater is transferred to these individual gas passages by thermal conduction. As a result, at least a part of the gas passage is in contact with the second heater and is heated by the second heater.

In a downstream region of a closing face of the valve, temperature of the material gas tends to fall due to adiabatic expansion. This tendency is also observed in the same way in a downstream region of a closing face of the flow control valve which the mass flow controller comprises. By preferentially heating these areas of the valve and mass flow controller, the temperature fall and condensation of the material gas in association with the adiabatic expansion can be effectively prevented.

As specific means for heating the gas passage which the valve comprises by the second heater in contact with the valve, for example, a means for making a surface of the second heater contact with a surface of a member constituting a body of the valve (valve box) and/or a means for making an intermediate member consisting of a material with high thermal conductivity intervene between the second heater and the valve body, etc. can be adopted. As specific means for heating the gas passage which the mass flow controller comprises by the second heater in contact with the mass flow controller, for example, a means for making a surface of the second heater contact with a surface of a member constituting a body (base) of the mass flow controller and/or a means for making an intermediate member consisting of a material with high thermal conductivity intervene between the second heater and the body of the mass flow controller can be adopted.

In a preferable embodiment of the present invention, the number of the gas passage which leads the material gas from the vaporization part to the outside may be one, two, or more than two. When the amount of the material gas generated per unit time in the vaporization part is sufficiently large, the more the number of the gas passage is increased, the more the flow rate of the material gas can be raised without raising the pressure of the material gas. When the vaporizer according to the present invention comprises a plurality of the gas passages, each of the gas passages may comprise a valve and a mass flow controller, or a single valve or mass flow controller may open and close or control the flow rate in a plurality of the gas passages simultaneously. A manifold for branching or merging the gas passages may be provided in the middle of the gas passage from the vaporization part to the outside.

### <Case>

In a preferable embodiment of the present invention, the vaporizer further comprises a case which houses the vaporization part, the gas passage, the first heater and the second heater. The case is a container which houses the entire constituting members of the vaporizer according to the present invention. The vaporizer which comprises the case can supply the material gas more stably since such a vaporizer is unlikely to be affected by changes in surrounding environment, namely, temperature, humidity, wind velocity, corrosive gases, static electricity, dust, etc., as compared with a vaporizer which does not comprise a case. In addition, even if the vaporizer malfunctions and the material gas leaks from the vaporizer to the outside by any chance, the extent of damage caused by the leak can be limited by the case.

The case in the above-mentioned preferable embodiment does not need to have a function for stirring the air inside, like the air thermostatic chamber disclosed in Patent Literature 2, and does not be constituted by a completely sealed container. As a material constituting the case, for example, a plate material consisting of a metal or alloy is preferred since they have sufficient strength in spite of being thin and therefore the entire size of the vaporizer can be reduced.

It is preferable that the case in the above-mentioned preferable embodiment further comprises a heat insulation means. When the case comprises the heat insulation means, release of heat generated in the first and second heaters to the outside of the vaporizer is suppressed, and most of the generated heat can be used for heating the vaporization part and the gas passage with less waste. Although the heat insulation means may be provided on either the inner or outer side of the container constituting the case, it is preferable for the heat insulation means to be provided on the inner side of the container in terms of handling and aesthetics of the vaporizer. The heat insulation means may be provided on the entire surface of the container constituting the case, or may be provided partially only at positions where heat insulation is particularly needed.

As specific examples of the heat insulation means, a porosity sheet formed of a material such as silicone rubber and/or ethylene propylene diene rubber (EPDM) can be attached to the inside of the case, for example. As a material of the container itself constituting the case, a material with high thermal insulation performance may be adopted.

### <Power Consumption per Unit Area>

In a preferable embodiment of the present invention, at least one of the first and second heaters is constituted by a planar heating element, and the heating element has a part with a large electric power consumption per unit area and a part with a small electric power consumption per unit area. In the present specification, “electric power consumption per unit area” is also referred to as “watt density”, and refers to a value obtained by dividing electric power consumed in a certain region of a planar heating element by the area of the region. Electric power per unit area is nothing other than the amount of heat generated by the heating element in the region. When heat transfer in an in-plane direction of the heating element is ignored, this heating value is the sum of heat generated from front and back surfaces of the heating element.

The parts with high and low electric power consumption per unit area can be provided in a planar heating element by providing a dense part and a sparse part of the heating resistive wires per unit area and/or providing a part with a high resistance value per unit length of the heating resistive wire and a part with a low resistance value per unit length of the heating resistive wire in the heating element, and so on, for example. By placing the part with high electric power consumption per unit area at a position where the temperature of the precursor or the material gas falls significantly and placing the part with low electric power consumption per unit area at a position where the temperatures do not fall so much, a position requiring heat can be preferentially heated while reducing the total amount of electric power consumed by the heater.

### <Third Heater>

In a preferable embodiment of the present invention, the vaporizer further comprises a third heater which heats the gas passage and does not heat the vaporization part. The third heater is a part separate and independent from the above-mentioned first and second heaters. The third heater is used exclusively to heat the gas passage. It is preferable that the third heater is provided at a position which is the farthest from the vaporization part and the second heater and close to the outside of the vaporizer, accordingly at a position where the temperature of the material gas is most likely to fall, in the gas passage. Thereby, condensation of the material gas can be prevented with less electric power consumption than that when the entire interior of the vaporizer is heated. A specific configurations of the third heater can include a heating resistive element, electric wires and a temperature sensor, as in the case of the first and second heaters. When there is only one gas passage, one third heater is usually sufficient. However, it is permissible in the present invention to provide a plurality of the third heaters for a special purpose.

### 2. Second Embodiment

In the second embodiment, the present invention is an invention of a method for supplying a material gas to semiconductor producing equipment by using a vaporizer comprising a vaporization part which vaporizes a precursor to generate the material gas, a gas passage which leads the generated material gas to the outside from the vaporization part, a first heater which heats the vaporization part and does not heat the gas passage, and a second heater which heats both the vaporization part and the gas passage, in which electric power supplied to the first heater and electric power supplied to the second heater are controlled such that temperature of the gas passage becomes higher than temperature of the precursor in the vaporization part. Since the configuration of the vaporizer used in the invention of this method is the same as the configuration of the vaporizer in the above-mentioned first embodiment, explanation thereof is omitted here.

In the method according to the present invention, the electric power supplied to the first heater and the electric power supplied to the second heater are controlled such that temperature of the gas passage becomes higher than temperature of the precursor in the vaporization part. As mentioned above, although the precursor in the vaporization part is heated by the first and second heaters, the heating by the first heater is primary and the heating by the second heater is auxiliary. Therefore, for example, the temperature of the precursor in the vaporization part can be measured by a temperature sensor or other means, and the electric power supplied to the first heater can be controlled so as to keep the temperature within a predetermined range. On the other hand, the gas passage is heated by the second heater. Therefore, for example, the temperature of the gas passage can be measured by a temperature sensor or other means, and the electric power supplied to the second heater can be controlled such that the temperature is higher than that of the precursor. However, specific means for controlling the temperature of the gas passage so as to be higher than the temperature of the precursor in the vaporization part is not limited to the above-mentioned means.

The temperature of the precursor in the vaporization part is an indicator of the temperature of the material gas vaporized in the vaporization part. An actual temperature of the material gas immediately after being vaporized in the vaporization part is considered to be slightly lower than the temperature of the precursor since latent heat of vaporization is lost through vaporization. In addition, it is generally more difficult to accurately measure the temperature of the material gas as compared with the temperature of the liquid or solid precursor. Therefore, the temperature of the precursor in the vaporization part is measured more reliably in the method according to the present invention, instead of directly measuring the temperature of the material gas. The temperature of the precursor can be measured, for example, by a temperature sensor provided inside the vaporization part.

In the present invention, the “temperature of the gas passage” refers to the temperature of the piping, a body of the valve (valve box) or a body (base) of the mass flow controller which constitute the gas passage. When measuring the temperature of the gas passage, it is ideal to measure the temperature of the inner surface of the gas passage in contact with the material gas. However, since this involves technical difficulties, a temperature of a part of the piping, the body of the valve (valve box) or the body (base) of the mass flow controller, which is exposed to the outside air, may be measured and considered as the temperature of the gas passage. Alternatively, a hole for inserting a temperature sensor may be provided inside a part of these parts, and the temperature inside the hole may be measured.

In the method according to the present invention, as a result of controlling the electric power supplied to the first heater and the electric power supplied to the second heater, the temperature of the gas passage can be higher than the temperature of the precursor in the vaporization part. As mentioned above, the temperature of the material gas flowing into the gas passage from the vaporization part is considered to be lower than the temperature of the precursor in the vaporization part. Therefore, by means of the above-mentioned temperature control to keep the temperature of the gas passage higher than the temperature of the precursor in the vaporization part, the temperature of the gas passage can be kept higher than the temperature of the material gas flowing through the gas passage, and condensation of the material gas in the gas passage can be prevented certainly.

### Working Example

### <First Working Example>

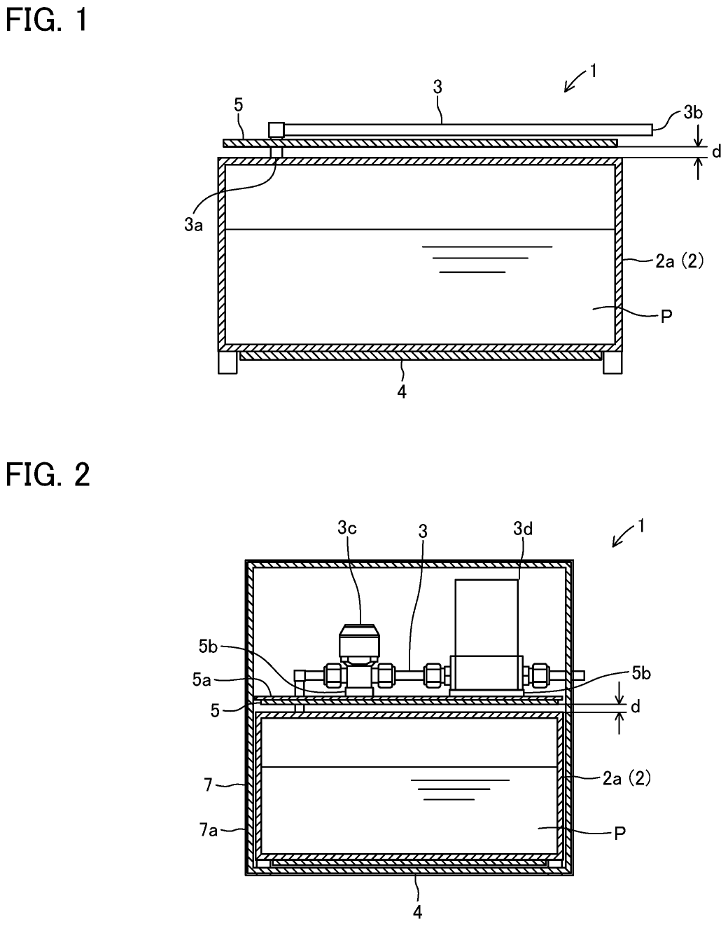

Embodiments of the present invention will be explained below more specifically, referring to drawings. FIG. 1 is a fragmentary sectional view for showing an example of a vaporizer according to the present invention. This vaporizer 1 adopts a baking method as a means of vaporizing the precursor P, and comprises the vaporization part 2 constituted by the tank 2a for storing and vaporizing the liquid precursor P. The liquid precursor P is injected into the vaporization part 2 from the outside by means of piping which is not shown. A temperature sensor which is not shown is provided inside the vaporization part 2 for measuring the temperature of the precursor P.

The gas passage 3 is provided in the upper part of the vaporization part 2. The gas passage 3 can be constituted by piping, etc., for example. The gas passage 3 begins at the outflow part 3a provided on the top surface of the tank 2a constituting the vaporization part 2 and ends at the supply port 3b. A temperature sensor which is not shown is provided in the gas passage 3.

The first heater 4 is provided outside the bottom part of the vaporization part 2. The first heater 4 in this working example is a planar heater constituted by a rubber heater with a heating resistance wire molded in rubber. The first heater 4 is provided in contact with the bottom surface that is a part of the vaporization part 2 and is not in contact with the gas passage 3. The heat generated in the first heater 4 is transferred to the precursor P through the bottom surface of the vaporization part 2 by thermal conduction. The material gas generated from the liquid surface of the heated precursor P stays at the upper part of the vaporization part 2, reaches the supply port 3b through the gas passage 3 from the outflow part 3a, and is supplied therefrom to the semiconductor producing equipment through external piping which is not shown.

The second heater 5 is provided on the outside of the upper surface of the vaporization part 2. As in the case of the first heater 4, the second heater 5 in this working example is a planar heater constituted by a rubber heater with a heating resistance wire molded in rubber. The second heater 5 is provided not in contact with the vaporization part 2. Namely, there is the gap d with a certain distance between the bottom surface of the second heater 5 and the top surface of the vaporization part 2. The size of this gap d is adjusted to be not less than 2.0 mm and not more than 5.0 mm. Because of this gap d, the heat generated in the second heater 5 is transferred to the vaporization part 2 not by thermal conduction, but mainly by thermal radiation.

A spacer which is not shown is intervened between the second heater 5 and the vaporization part 2 to keep the gap d between them at a certain value. Since the cross-sectional area of the spacer is small, the amount of heat transferred from the second heater 5 to the vaporization part 2 by heat conduction through the spacer is sufficiently small to be ignored as compared with the amount of heat transferred by thermal radiation.

On the other hand, the second heater 5 is provided in contact with the gas passage 3. Specifically, a top surface of the second heater 5 is in contact with a lower part of the gas passage 3. Thereby, a part of the heat generated in the second heater 5 is transferred to the gas passage 3 by thermal conduction. Although there is a gap between the top surface of the second heater 5 and the lower part of the gas passage 3 In FIG. 1, this gap is simply provided such that they can be seen as separate parts. In fact, the top surface of the second heater 5 and the lower part of the gas passage 3 are in contact with each other in the sense defined in the present specification.

In the vaporizer 1 according to this example, the tank 2a constituting the vaporization part 2 is sandwiched between the first heater 4 provided on its lower surface and the second heater 5 located above it. This configuration can maintain a state where the temperature distribution inside the vaporization part 2 is uniform even when the liquid level of the precursor P stored in the vaporization part 2 fluctuates. In addition, since no heater is provided on the side surface of the vaporization part 2, almost the entire installation area of vaporizer 1 can be devoted to the vaporization part 2.

In order to supply the material gas to the semiconductor producing equipment using the vaporizer 1 according to this working example, the electric power supplied to the first heater 4 and the electric power supplied to the second heater 5 are controlled such that the temperature of the gas passage 3 is higher than the temperature of the precursor P in the vaporization part 2. Thereby, condensation of the material gas in the gas passage 3 can be prevented. In order to control the electric power supplied to these two heaters, for example, a power supply and control circuit which are not shown can be operated based on the temperature of the precursor P and the temperature of the gas passage as measured by a temperature sensor. The power supply and control circuit may be built in the vaporizer 1 or constituted as a unit separate from the vaporizer 1.

### <Second Working Example>

FIG. 2 is a fragmentary sectional view for showing another example of the vaporizer according to the present invention. In this working example, the valve 3c and the mass flow controller 3d are connected in the middle of the gas passage 3. The valve 3c and mass flow controller 3d comprise individual gas passages in themselves. Piping constituting the gas passage 3 and the individual gas passages which the valve 3c and mass flow controller 3d comprise are joined together to constitute the gas passage 3 in the vaporizer 1.

The second heater 5 has its upper surface side stuck to the heater plate 5a, and the valve 3c and the mass flow controller 3d are fixed to the upper surface of the heater plate 5a through the intermediate member 5b. The heater plate 5a and intermediate member 5b in this working example are constituted of aluminum alloy with high thermal conductivity. A thickness of the heater plate 5a is adjusted to be not less than 5.0 mm and not more than 10 mm. Thereby, the temperature distribution in the in-plane direction of the second heater 5 and the heater plate 5a becomes uniform. A part of the heat generated in the second heater 5 is transferred to the valve 3c and the mass flow controller 3d by thermal conduction through the heater plate 5a and the intermediate member 5b. Also in the example shown in FIG. 2, as in the case of the example shown in FIG. 1, the second heater 5 is provided not in contact with the vaporization part 2. Namely, there is the gap d of a certain distance between the bottom surface of the second heater 5 and the upper surface of the vaporization part 2.

The entire of the vaporization part 2, the gas passage 3, the first heater 4 and the second heater 5 are housed in the case 7 which is constituted by a metal plate. Inside the case 7, a sheet made of silicone rubber is stuck to the entire surfaces as heat insulation means 7a. Thereby, the electric power efficiency of the first heater 4 and the second heater 5 can be increased since heat is prevented from being released from the bottom surface and side surfaces of the vaporization part 2 and a space above the gas passage 3 to the outside of the vaporizer 1.

### <Third Working Example>

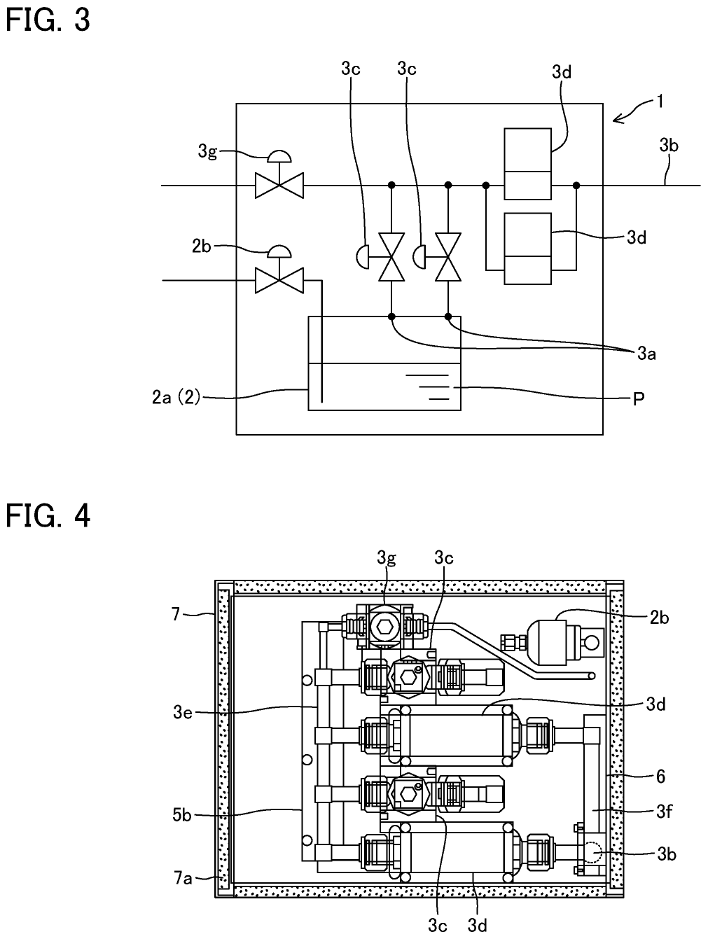

FIG. 3 is a piping diagram of a working example of a vaporizer according to the present invention, which is similar to an actual product. In this third working example, unlike the first and second working examples, two gas passages 3 are provided instead of one. Namely, there are two outflow parts 3a from which the material gas flows out of the tank 2a, and one valve 3c is provided in each of the gas passages. The gas passages merge once at the outflow part of the valve 3c, and thereafter branch off to two mass flow controllers 3d. The gas passages merge again at the outflow parts of the mass flow controllers 3d, and the material gas is supplied to the outside from the supply port 3b. In this way, large flow rates can be handled. The precursor P is supplied to the vaporization part 2 from the precursor supply valve 2b and stored in the vaporization part 2. When the material gas is to be discharged from the gas passage 3, a purge gas is introduced into the gas passage 3 from the purge gas valve 3g.

FIG. 4 is a top view of the vaporizer according to the third working example. In Fig, 4, arrangement of members and piping on the upper surface of the tank 2a is shown. The material gas generated in the tank 2a flows out of the two outflow parts 3a which are not shown and, after passing through the two valves 3c, reaches the first manifold 3e to merge. This first manifold 3e is in contact with the upper surface of the second heater 5 via the intermediate member 5b in connection with the second heater 5 located in the upper part of the tank 2a. In addition, the two valves 3c also have their bottom parts in contact with the upper surface of the second heater 5 via the intermediate member 5b. Next, the material gas branches from the first manifold 3e to the piping of the two mass flow controllers 3d, passes through the mass flow controllers 3d, thereafter reaches the second manifold 3f to merge, and is supplied to the outside through one supply port 3b. Moreover, the vaporizer 1 according to the third working example further comprises the third heater 6 which heats the gas passage 3. Details of the third heater 6 will be mentioned later.

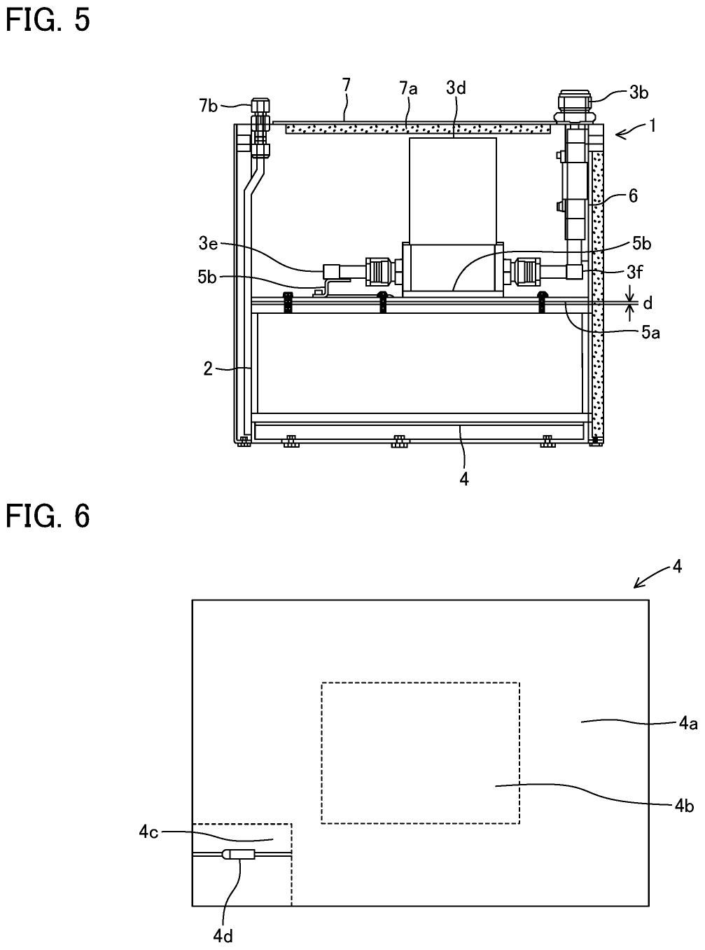

FIG. 5 is a fragmentary sectional side view of the vaporizer according to the third working example. In FIG. 5, the mass flow controller 3d is shown, and the valve 3c is hidden behind the mass flow controller 3d and not visible since the valve 3c is located at the same position as the mass flow controller 3d in the side view. As shown, the intermediate member 5b supporting the first manifold 3e is L-shaped and is screwed to the upper surface of the second heater 5. This intermediate member 5b is constituted of aluminum alloy plate which transfers heat easily. The entire vaporizer 1 is enclosed in the case 7, and the heat insulation means 7a is provided on a part of the inner side of the case 7. The purge gas piping 7b is provided to supply purge gas to the inside of the case 7. In the vaporizer 1 according to the third working example shown in FIG. 5, the distance of the gap d between the top surface of the tank 2a and the lower surface of the second heater 5 is 3.0 mm.

FIG. 6 is a plan view of the first heater 4 according to the third working example. The first heater 4 is constituted by a planar rubber heater having approximately the same shape as that of the bottom surface of the tank 2a. In the bottom surface of the tank 2a, heat dissipation at a center part thereof is smaller than that at peripheral parts, and its temperature does not drop easily. Therefore, in the first heater 4 shown in FIG. 6, the electric power efficiency of the first heater 4 is improved by configuring such that the electric power consumption per unit area in the peripheral part 4a in contact with the peripheral part of the tank 2a is larger than the electric power consumption per unit area in the central part 4b in contact with the central part of the tank 2a.

The thermal fuse 4d is provided in one corner of the first heater 4 shown in FIG. 6 for the purpose of preventing the first heater 4 from being excessively heated. Sensitivity of the thermal fuse 4d is enhanced by configuring such that the electric power consumption per unit area at a position of the part 4c where the thermal fuse 4d is provided is further smaller than that of the central part 4b. The electric power consumptions per square centimeter of respective parts in this working example of the first heater 4 are exemplified as 0.9 watts for the peripheral part 4a, 0.6 watts for the central part 4b and 0.4 watts for the part 4c.

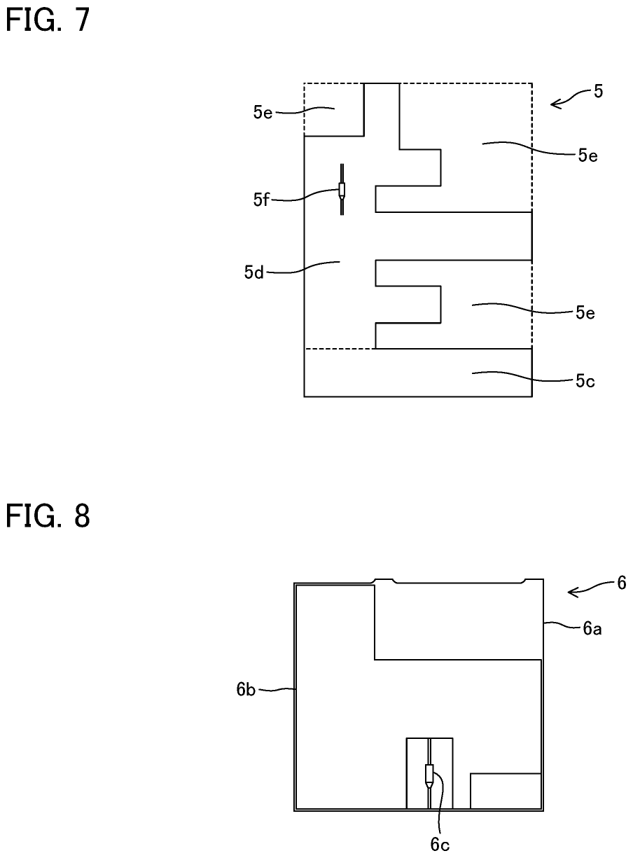

FIG. 7 is a plan view for showing the second heater 5 according to the third working example. FIG. 7 is drawn with the same scale and orientation as those of the top view of FIG. 4. The second heater 5 is configured by a planar rubber heater whose maximum horizontal and vertical dimensions are approximately the same as those of the upper surface of the tank 2a. The part 5c in FIG. 7 corresponds to a position where the mass flow controller 3d located on an outer side out of the two mass flow controllers 3d shown in FIG. 4 is arranged, and has the largest electric power consumption per unit area. This is because the amount of heat which escapes to the outside of the case 7 is larger than as compared with that at the position where the mass flow controller 3d located inside is arranged. The part 5d corresponds to a position where the valve 3c is arranged and the electric power consumption per unit area in the part 5d is adjusted to be lower than that in the part 5c since the temperature fall at the position where the valve 3c is arranged (corresponding to the part 5c) is smaller than that at the position where the mass flow controller 3d is arranged (corresponding to the part 5d). Thereby, the electric power efficiency of the second heater 5 is improved.

The part 5e where the second heater 5 is cut out in a rectangular shape in FIG. 7 is a defective part where the second heater 5 is not provided since there is no member to be heated as shown in FIG. 4. The heat generated in the second heater 5 is transferred to the side of the vaporization part 2 by thermal radiation and to the side of the gas passage 3 by thermal conduction through the heater plate 5a and the intermediate member 5b. As in the case of the first heater 4, the thermal fuse 5f is provided in a part of the second heater 5 shown in FIG. 4 for the purpose of preventing the second heater 5 from being excessively heated. The electric power consumptions per square centimeter of respective parts in this working example of the second heater 5 are exemplified as 1.0 watt for the part 5c, 0.7 watt for the part 5d and zero for the defective part 5e.

FIG. 8 is a plan view for showing a third heater according to the third heater 6 according to the third working example. The third heater 6 has a structure in which the rubber heater 6b is stuck to a part of the heater plate 6a. The heater plate 6a is constituted by an aluminum plate with a thickness of 20 mm, and is processed into a shape into which the gas passage 3 including the manifold 3e just fits. This configuration allows the heat generated by the rubber heater 6b to reach the gas passage 3 through the heater plate 6a. As in the case of the first heater 4 and the second heater 5, the thermal fuse 6c is provided in a part of the third heater 6 shown in FIG. 8 for the purpose of preventing the third heater 6 from being excessively heated. The electric power consumption per square centimeter of the rubber heater 6b in this working example of the third heater 6 is 0.8 watts.

Next, effects of the present invention will be specifically explained by showing an example of the temperature settings for respective parts in the vaporizer 1 when vaporizing tetraethoxysilane (TEOS) that is a kind of a material gas using the vaporizer 1 according to the above-mentioned third working example. The vaporizer 1 comprises a first sensor which measures a first temperature that is a temperature of the precursor P stored in the tank 2a, and a second sensor which measures a second temperature that is a temperature of a member constituting a body (base) of the mass flow controller 3d located on an outer side out of the two mass flow controllers 3d in FIG. 4. Although none of these sensors are shown, they are platinum resistance thermometers or thermocouples. The first heater 4 is feedback-controlled such that the first temperature matches a predetermined temperature, and the second heater 5 is feedback-controlled such that the second temperature matches a preset temperature. The third heater 6 is configured such that a temperature of a part of the gas passage 3 heated by the third heater 6 is higher than a temperature of a part of the gas passage 3 heated by the second heater 5.

The configuration as mentioned above can be realized by disposing a temperature sensor also in the part of the gas passage 3 heated by the third heater 6 and feedback-controlling the third heater 6 such that a temperature detected by the temperature sensor is higher than the second temperature, for example. However, in this case, the number of constituents of the vaporizer 1 increases, the overall control becomes more complicated, and problems such as an increase in the cost of the vaporizer 1 may occur. Moreover, as mentioned above, it is preferable that the third heater 6 is provided at a position which is the farthest from the vaporization part 2 and the second heater 5 and close to the outside of the vaporizer 1, accordingly at a position where the temperature of the material gas is most likely to fall, in the gas passage 3. Generally, a part in the gas passage 3 at such a position is piping which includes neither the valve 3c nor the mass flow controller 3d. Namely, as for this part, there is relatively little need to be concerned about problems such as deterioration of the components constituting the valve 3c and/or the mass flow controller 3d due to high temperature, decrease in flow accuracy, and decrease in reliability. Therefore, the temperature in this part only needs to be maintained at a sufficiently high temperature to ensure that condensation of the material gases can be avoided.

Therefore, in the vaporizer 1 according to the third working example, the third heater 6 is connected in parallel with the second heater 5 with respect to the power source, and is configured so as to be controlled based on the second temperature. However, in the vaporizer 1, the third heater 6 is configured such that the temperature of the part of the gas passage 3 heated by the third heater 6 is higher than the temperature of the part of the gas passage 3 heated by the second heater 5. Such a configuration can be achieved by designing the watt density (electric power consumption per unit area) of the third heater 6 appropriately for the heat capacity of the part of the gas passage 3 heated by the third heater 6, for example. As a result, the temperature of the part of the gas passage 3 heated by the third heater 6 can be maintained somewhat higher than the temperature of the part of the gas passage 3 heated by the second heater 5.

In the vaporizer 1 according to the third working example, which has the configuration as mentioned above, after storing tetraethoxysilane in the inside of the tank 2a via the precursor supply valve 2b, the first heater 4 and the second heater 5 were feedback-controlled such that the first and second temperatures coincide with 89.0° C. and 91.0° C., respectively, in a state where the valve 3c is closed, and the temperatures of respective parts were stabilized by maintaining such a control state for 180 minutes. The third heater 6 was connected in parallel with the second heater 5 to the power supply and was configured so as to be controlled based on the second temperature, as mentioned above. Thereafter, the temperatures of the respective parts in the vaporizer 1 were measured using a platinum resistance thermometer or thermocouple.

As the result of the measurement, in order from the upstream side of the gas passage 3, the temperature of the side surface of an elbow of the piping from the outflow 3a in the upper part of tank 2a to the valve 3c was 88.6° C., the temperature of the side surface of the first manifold 3e on the side of the outflow part of valve 3c was 93.1° C., the temperature of the joint at the inlet part of the mass flow controller 3d located outside out of the two mass flow controllers 3d in FIG. 4 was 91.2° C., the temperature of the outer side out of the side surfaces of the base of the same mass flow controller 3d was 96.1° C., the temperature of the both side surfaces of the base of the mass flow controller 3d located inside out of the two mass flow controllers 3d in FIG. 4 was 93.5° C. and 94.0° C., respectively, and the temperature of the piping at the position of the supply port 3b above the third heater 6 was 100.9° C.

From the above results, it can be found that the temperatures at all positions in the gas passage 3 are maintained at temperatures equal to or higher than a set temperature of the tank 2a in the vaporizer 1 according to the third working example. Thereby, condensation of the material gas inside the gas passage 3 is prevented. In addition, it can also be found that variation in the temperatures of the side surfaces of the bases of the two mass flow controllers 3d were within 3.0° C. Thereby, accuracy of the flow control of the material gas by the mass flow controller 3d is maintained. Furthermore, it can be found that the variation in the temperature of the gas passage 3 is within 10° C., except for a position of the supply port 3b which corresponds to the most downstream position in the gas passage 3. Thereby, reliability of the entire vaporizer can be ensured since the parts constituting respective members are not excessively heated.

Although a holding temperature of the precursor was set at 89° C. in the above-mentioned example, it is expected that opportunities to use material gases whose precursor should be hold at higher temperatures will increase as applications of vaporizers expand in the future. There is a tendency that the higher the holding temperature of precursor becomes, the larger a temperature difference among respective parts of a vaporizer becomes. Even in such cases, in accordance with the vaporizer and the method of supplying material gas according to the present invention, since the temperature distribution inside the vaporizer can be brought closer to a uniform state, there is no need to deliberately adopt parts with higher heat resistance temperatures and/or consume unnecessary electric power in parts which become excessively hot. Therefore, the vaporizer and the method of supplying material gas according to the present invention are more economical.

1. A vaporizer which supplies a material gas to semiconductor producing equipment, comprising:
a vaporization part which vaporizes a precursor to generate said material gas,
a gas passage which leads said generated material gas to the outside from said vaporization part,
a first heater which heats said vaporization part and does not heat said gas passage, and
a second heater which heats both said vaporization part and said gas passage, wherein:
said second heater itself has a planar shape,
said vaporization part is located on a side of one surface of said second heater, and
said gas passage is located on a side of the other surface of said second heater.

2. The vaporizer according to claim 1, wherein:
said vaporization part is not in contact with said one surface of said second heater, and
said gas passage is in contact with said other surface of said second heater.

3. The vaporizer according to claim 2, wherein:
said first heater has a planar shape, and
said vaporization part is in contact with one surface of said first heater.

4. The vaporizer according to claim 3, wherein:
said precursor is a liquid,
said vaporization part is a tank which contains said precursor, and
said first heater and said second heater are arranged at positions facing each other across said tank.

5. The vaporizer according to claim 4, wherein:
said first heater is located in a bottom part of said tank, and
said second heater is located in an upper part of said tank.

6. The vaporizer according to claim 1, wherein:
said gas passage includes a valve and a mass flow controller.

7. The vaporizer according to claim 1, wherein:
said vaporizer comprises a case which houses said vaporization part, said gas passage, said first heater and said second heater.

8. The vaporizer according to claim 7, wherein:
said case comprises a heat insulation means.

9. The vaporizer according to claim 1, wherein:
at least one of said first heater and said second heater has a part with a large power consumption per unit area and a part with a small power consumption per unit area.

10. The vaporizer according to claim 1, wherein:
said vaporizer further comprises a third heater which heats said gas passage and does not heat said vaporization part.

11. A method for supplying a material gas to semiconductor producing equipment by using a vaporizer, the method comprising:
vaporizing a precursor with a vaporization part to generate said material gas,
leading, with a gas passage, said generated material gas to an outside from said vaporization part,
heating, with a first heater, said vaporization part without heating said gas passage, and
heating, with a second heater, both said vaporization part and said gas passage, and:
controlling electric power supplied to said first heater and electric power supplied to said second heater such that a temperature of said gas passage becomes higher than a temperature of said precursor in said vaporization part.

12. The method according to claim 11, comprising:
heating, with a third heater, said gas passage without heating said vaporization part, and
wherein a temperature of a part of said gas passage, which is heated with said third heater, becomes higher than a temperature of a part of said gas passage, which is heated with said third heater, becomes higher than a temperature of a part of said gas passage, which is heated with said second heater.
